(19) United States
(12) Patent Application Publication
(10) Pub. No.: US 2024/0304562 A1
(43) Pub. Date: Sep. 12, 2024

(54) SEMICONDUCTOR DEVICE AND MANUFACTURE METHOD

(71) Applicant: NANYA TECHNOLOGY CORPORATION, New Taipei City (TW)

(72) Inventors: Ding Lun LIN, New Taipei City (TW); Kie-Dong CHEN, Taipei City (TW)

(21) Appl. No.: 18/181,584

(22) Filed: Mar. 10, 2023

(51) Int. Cl. H01L 23/544; G01B 15/00

(52) U.S. Cl. CPC H01L 23/544; G01B 15/00; H01L 2223/54426

(57) ABSTRACT

A semiconductor device includes a substrate and an overlapping layer disposed on the substrate body. The substrate has a substrate body and a plurality of detection regions disposed on a top surface of the substrate body, in which one of the plurality of detection regions includes a luminescent material. The overlapping layer has a plurality of holes, and each one of the plurality of detection regions corresponds to each one of the plurality of holes. A method of manufacturing a semiconductor device is further provided.

### BACKGROUND

### Field of Invention

The present disclosure relates to a semiconductor device and a method of manufacturing a semiconductor device.

### Description of Related Art

An issue of failing to detect overlay errors of holes (or trenches) through secondary electrons (such as using a scanning electron microscope (SEM)) exists while the holes (or the trenches) have a high aspect ratio.

For the foregoing reason, there is a need to solve the above-mentioned problem by providing a semiconductor device in which the overlay errors of the holes (or the trenches) can be detected regardless of whether the holes (or the trenches) have the high aspect ratio.

### SUMMARY

Some embodiments of the present disclosure provide a semiconductor device including a substrate and an overlapping layer disposed on the substrate body. The substrate has a substrate body and a plurality of detection regions disposed on a top surface of the substrate body, in which one of the plurality of detection regions includes a luminescent material. The overlapping layer has a plurality of holes, and each one of the plurality of detection regions corresponds to each one of the plurality of holes.

In the foregoing, the top surface of the substrate body has a plurality of recesses, and each one of the plurality of detection regions corresponds to and is disposed in each one of the plurality of recesses.

In the foregoing, a top surface of the plurality of detection regions is coplanar with the top surface of the substrate body, and the substrate body surrounds a bottom portion of each one of the plurality of detection regions.

In the foregoing, the substrate body includes a first metal material, and one of the plurality of detection regions includes a second metal material, wherein the second metal material is the luminescent material.

In the foregoing, the luminescent material includes Cu⁺, Ag⁺, In⁺, V²⁺, Co²⁺, Sn²⁺, Eu²⁺, Mn²⁺, Ni²⁺, Pb²⁺, Bi³⁺, Pr³⁺, Nd³⁺, Sm³⁺, Eu³⁺, Gd³⁺, Tb³⁺, Dy³⁺, Ho³⁺, Tm³⁺, Yb³⁺, Ti³⁺, Ce³⁺, or a combination thereof.

In the foregoing, each one of the plurality of detection regions corresponds to and is disposed in each one of the plurality of holes, and a bottom surface of each one of the plurality of detection regions is coplanar with the top surface of the substrate body.

In the foregoing, one of the plurality of holes has an aspect ratio of from 5:1 to 100:1.

In the foregoing, the semiconductor device further includes a plurality of filling pillars, in which each one of the plurality of filling pillars is disposed on each one of the plurality of detection regions.

In the foregoing, each one of the plurality of filling pillars is directly disposed on each one of the plurality of detection regions and fills up each one of the plurality of holes.

Some embodiments of the present disclosure provide a method of manufacturing a semiconductor device including providing a substrate body; disposing an overlapping layer on the substrate body; forming a plurality of holes in the overlapping layer and exposing an exposed portion of the substrate body; disposing a plurality of detection regions on the substrate body or in the substrate body through the plurality of holes, wherein one of the plurality of detection regions includes a luminescent material; providing an electron beam propagating toward the plurality of detection regions to emit a luminescent signal from one of the plurality of detection regions; and determining an overlay error of the plurality of holes by comparing a practical position of one of the plurality of holes detected by the luminescent signal with a theoretical position of one of the plurality of holes.

In the foregoing, disposing the plurality of detection regions on the substrate body through the plurality of holes includes disposing a detection material including the luminescent material on the exposed portion of the substrate body.

In the foregoing, disposing the plurality of detection regions in the substrate body through the plurality of holes includes doping the luminescent material in the substrate body by an ion-implanting method.

In the foregoing, the substrate body includes a first metal material, and the luminescent material is a second metal material.

In the foregoing, the method further includes providing the electron beam propagating toward the overlapping layer while providing an electron beam propagating toward the plurality of detection regions; and determining a surface image of the overlapping layer by detecting secondary electrons reflected by the overlapping layer.

In the foregoing, the method further includes disposing a plurality of filling pillars on the plurality of detection regions.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a flow diagram illustrating a method of manufacturing a semiconductor device in accordance with some embodiments;

FIGS. 2-4, FIG. 5A and FIGS. 6-7 and 8A are cross-sectional views of various intermediary stages in the manufacturing of a semiconductor device in accordance with some embodiments of this disclosure; and

FIGS. 5B and 8B are cross-sectional views of two intermediary stages in the manufacturing of a semiconductor device in accordance with some other embodiments of this disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

The terminology used herein is for the purpose of describing particular example embodiments only and is not intended to be limiting of the present disclosure. Single forms used in the present specification such as “a”, “one” and “the” includes multiple forms such as “at least one”; “or” represents “and/or” unless described clearly. As used herein, the term “and/or” includes any and all combinations of one or more of the associated listed items. It will be further understood that the terms “comprises”, “comprising”, and/or “has”, “have”, “having” when used in this specification, specify the presence of stated features, areas, integers, steps, operations, elements, and/or components, but do not preclude the presence or addition of one or more other features, areas, integers, steps, operations, elements, components, and/or groups thereof.

Embodiments of the present disclosure are described herein with reference to top illustrations that are schematic illustrations of idealized embodiments of the present disclosure. As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present disclosure.

Reference will now be made in detail to embodiments of the present disclosure, examples of which are described herein and illustrated in the accompanying drawings. While the disclosure will be described in conjunction with embodiments, it will be understood that they are not intended to limit the disclosure to these embodiments. Therefore, the scope of the present disclosure is to be limited only by the appended claims.

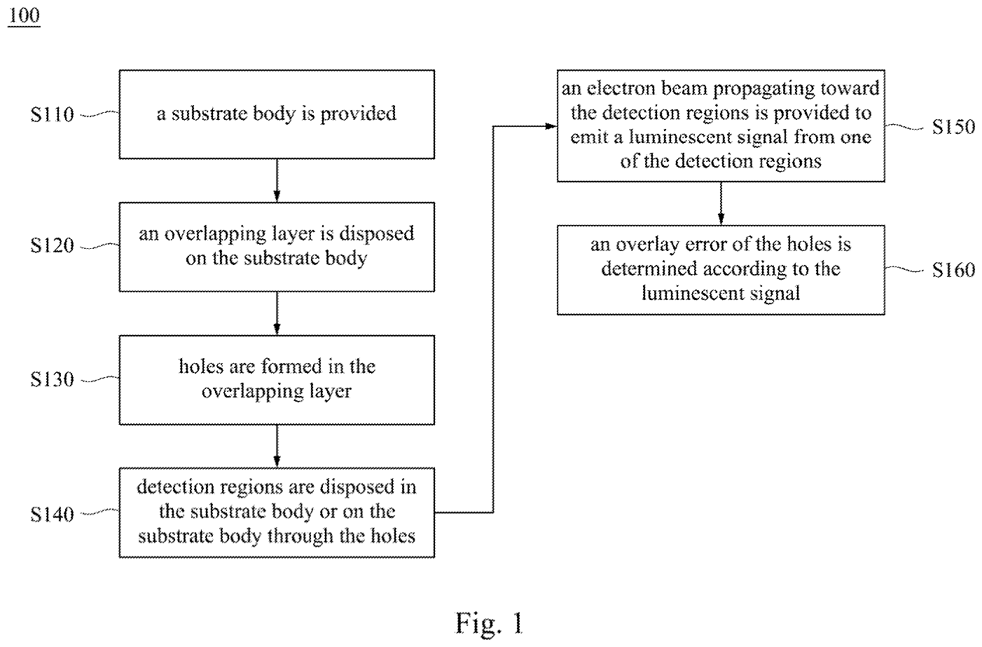

Referring to FIG. 1, illustrating a method 100 of manufacturing a semiconductor device, and the method 100 includes steps S110, S120, S130, S140, S150 and S160. The steps S110 to S160 of FIG. 1 are elaborated in connection with following figures.

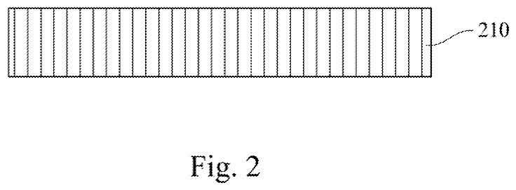

Referring to step S110 of FIG. 1 and FIG. 2, a substrate body 210 is provided.

In some embodiments, the substrate body 210 may include a first metal material, such as copper (Cu), copper alloy, aluminum (Al), aluminum alloy, tungsten (W), tungsten alloy, titanium (Ti), titanium alloy, tantalum (Ta), tantalum alloy, or a combination thereof. Alternatively, other applicable conductive materials may be used.

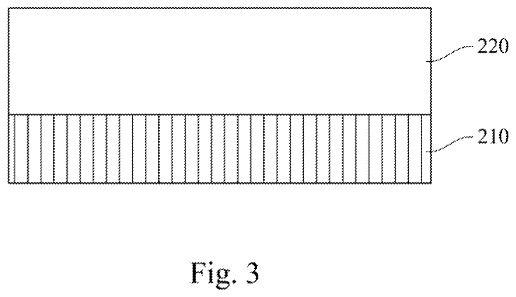

Referring to step S120 of FIG. 1 and FIG. 3, an overlapping layer 220 is disposed on the substrate body 210.

In some embodiments, the overlapping layer 220 may be, for example, a silicon substrate, a gallium arsenide substrate, a silicon germanium substrate, a silicon substrate on insulator (SOI) substrate, a multilayer or the like. For example, the overlapping layer 220 may be an insulating multilayer including an oxide layer and a carbon layer disposed on the oxide layer. In some other embodiments, the conductive materials may be used in the overlapping layer 220.

In some embodiments, the overlapping layer 220 may be formed on the substrate body 210 by suitable method such as chemical vapor deposition (CVD), physical vapor deposition (PVD), or the like.

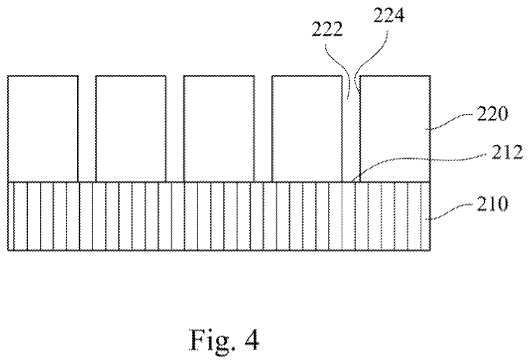

Referring to step S130 of FIG. 1 and FIG. 4, holes 222 are formed in the overlapping layer 220.

In some embodiments, an exposed portion 212 of the substrate body 210 is exposed after the holes 222 are formed. In some embodiments, the holes 222 have a high aspect ratio, such as from 5:1 to 100:1. For example, the holes 222 have an aspect ratio of 5:1, 6:1, 7:1, 8:1, 9:1, 10:1, 20:1, 30:1, 40:1, 50:1, 60:1, 70:1, 80:1, 90:1, 100:1, or a value within any interval defined by the above values. In some embodiments, the holes 222 are formed by patterning the overlapping layer 220. It is noted that an overlay error of the holes 222 cannot be determined precisely since practical positions of the holes 222 with the high aspect ratio can hardly be positioned by a scanning electron microscope (SEM). Specifically, secondary electrons reflected by a sidewall 224 of the overlapping layer 220 and the exposed portion 212 of the substrate body 210 cannot be received by the SEM due to the high aspect ratio of the holes 222.

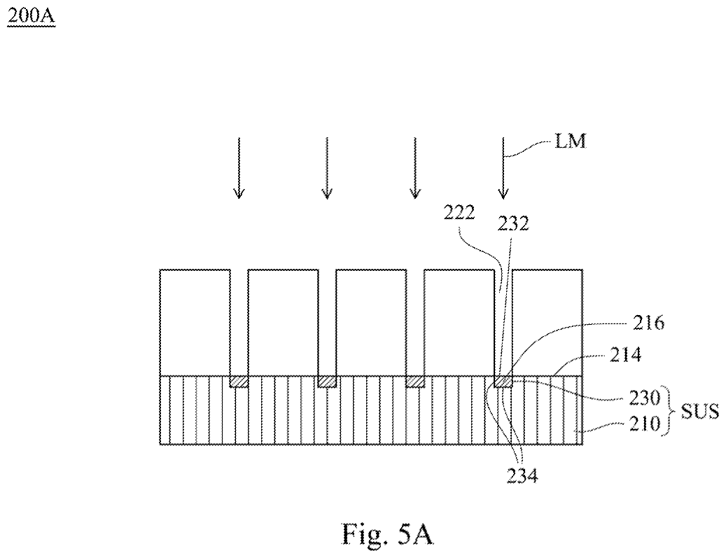

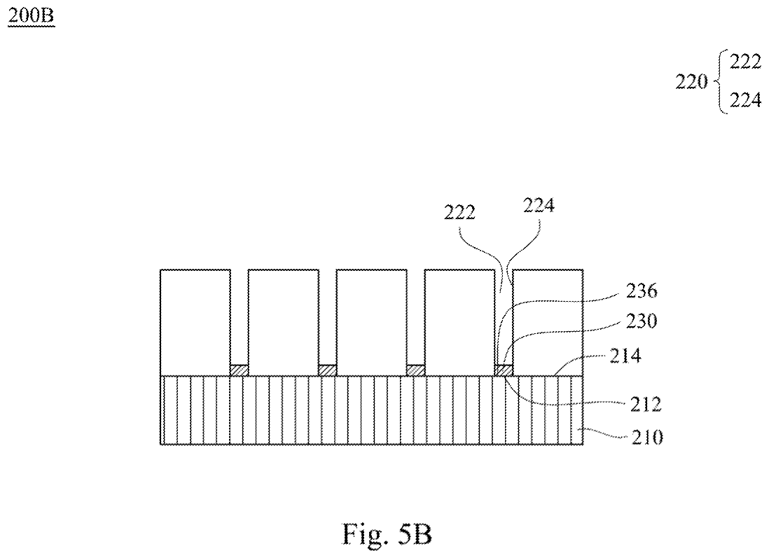

Referring to step S140 of FIG. 1 and FIG. 5A, detection regions 230 are disposed in the substrate body 210 through the holes 222. Therefore, a semiconductor device 200A is formed.

In some embodiments, the detection regions 230 and the substrate body 210 forms a substrate SUS, and each one of the detection regions 230 corresponds to each one of the holes 222 for detecting each of the position of the holes 222 in the following steps.

In some embodiments, the detection regions 230 are formed by doping the luminescent material LM, which can emit fluorescence or phosphorescence after absorbing enough energy, in the substrate body 210 by an ion-implanting method. That is, the detection regions 230 includes the first metal material of the substrate body 210 and the luminescent material LM doped in the first metal material. In some embodiments, the luminescent material LM is a second metal material, such as Cu⁺, Ag⁺, In⁺, V²⁺, Co²⁺, Sn²⁺, Eu²⁺, Mn²⁺, Ni²⁺, Pb²⁺, Bi³⁺, Pr³⁺, Nd³⁺, Sm³⁺, Eu³⁺, Gd³⁺, Tb³⁺, Dy³⁺, Ho³⁺, Tm³⁺, Yb³⁺, Ti³⁺, Ce³⁺, or a combination thereof, in which Nd³⁺ may be served as an excellent candidate due to sharp and intense luminescence.

It should be emphasized that conductivity interference of the detection regions 230 to the substrate body 210 can be reduced while the luminescent material LM is selected to be the second metal material comparing with selection of an insulating material served as the luminescent material LM.

In some embodiments, after performing the ion-implanting method, the detection regions 230 are merged in the substrate body 210 so that the semiconductor device 200A performs that a top surface 214 of the substrate body 210 has recesses 216, each one of the detection regions 230 corresponds to and is disposed in each of the recesses 216, in which the detection regions 230 are disposed on and contacts with the top surface 214 of the substrate body 210 for detecting each one of the position of the holes 222 in the following steps. In some embodiments, the top surface 232 of the detection regions 230 is coplanar with the top surface 214 of the substrate body 210, and the substrate body 210 surrounds a bottom portion 234 of each one of the detection regions 230.

It's noted that the disposition of the detection regions 230 merged in the substrate body 210 decreases the conductivity interference of the detection regions 230 to the substrate body 210 and can be easily performed by the ion-implanting method.

In some other embodiments, referring to step S140 of FIG. 1 and FIG. 5B, the detection regions 230 are disposed on the substrate body 210 through the holes 222.

FIG. 5B is basically similar to FIG. 5A. The difference of FIG. 5B and FIG. 5A is that the semiconductor device 200B of FIG. 5B displays that a detection material including the luminescent material LM (not shown in FIG. 5B) is disposed on the exposed portion 212 of the substrate body 210 to form the detection regions 230. Therefore, a semiconductor device 200B is formed.

In some embodiments, each one of the detection regions 230 corresponds to and is disposed in each one of the holes 222, and a bottom surface 236 of each one of the detection regions 230 is coplanar with the top surface 214 of the substrate body 210. That is, the bottom surface 236 of each one of the detection regions 230 directly contacts with the top surface 214 of the substrate body 210 and the sidewall 224 of the overlapping layer 220.

In some embodiments, the detection regions 230 are formed by suitable method such as chemical vapor deposition (CVD), physical vapor deposition (PVD) or the like. In some embodiments, the detection material contains the luminescent material LM (such as the second metal material, not shown in FIG. 5B) and an additive including an inorganic material, a polymer (such as resin), or a combination thereof. It should be emphasized that the conductivity interference of the detection regions 230 to the substrate body 210 can be reduced while the luminescent material LM (not shown in FIG. 5B) is selected to be the second metal material comparing with selection of the insulating material served as the luminescent material LM (not shown in FIG. 5B). In some other embodiments, the detection material is insulating and does not contain the conductive materials. For example, the luminescent material LM (not shown in FIG. 5B) includes fluorescent protein (such as green fluorescent protein (GFP), enhanced EGFP, blue fluorescent protein (BFP), cyan fluorescent protein (CFP), red fluorescent protein (RFP), white GFP (wtGFP), yellow fluorescent protein (YFP), dsRed, mCherry, mVenus, mCitrine, tdTomato, mTurquoise2 or the like), but does not include the second metal material.

It's noted that the disposition of the detection regions 230 in the holes 222 and the bottom surface 236 of the detection regions 230 being coplanar with the top surface 214 of the substrate body 210 can be easily performed by semiconductor processes (such as CVD or PVD) and does not influence the structure of the substrate body 210.

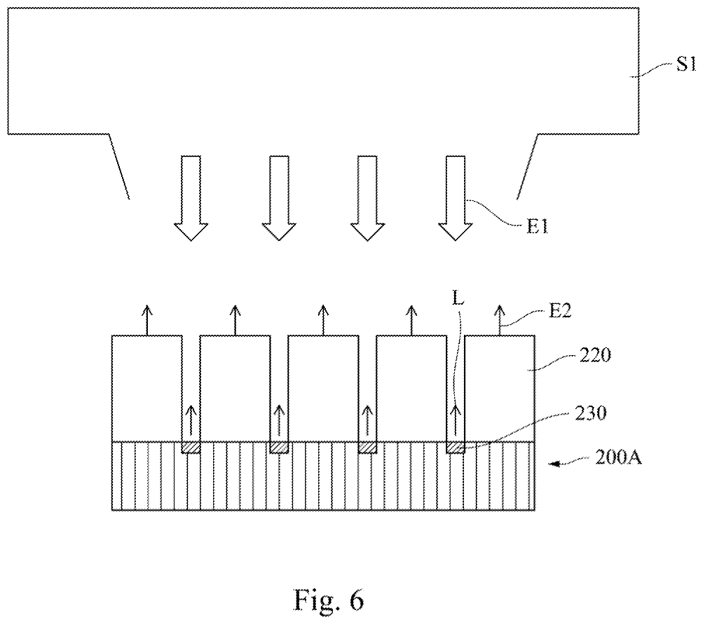

Referring to step S150 of FIG. 1 and FIG. 6, an electron beam E1 propagating toward the detection regions 230 is provided to emit a luminescent signal L from one of the detection regions 230, in which the semiconductor device 200A is provided merely for demonstration and is not limited thereto.

In some embodiments, an electron beam E1 propagating toward the detection regions 230 is provided to emit the luminescent signals L from each one of the detection regions 230 while each one of the detection regions 230 includes the luminescent material LM.

In some embodiments, the electron beam E1 is generated by a charged particle source S1, such as SEM. The electron beam E1 provides the detection regions 230 with enough energy to allow the luminescent material LM (not shown in FIG. 6) to emit the luminescent signal L. In some embodiments, the electron beam E1 propagates toward the overlapping layer 220 as propagating toward the detection regions 230, and then a surface image of the overlapping layer 220 is determined by detecting secondary electrons E2 reflected by the overlapping layer 220 by using the charged particle source S1. That is, the electron beam E1 is provided for generating the surface image of the overlapping layer 220 and the luminescent signal L from the detection regions 230 for the further positioning simultaneously.

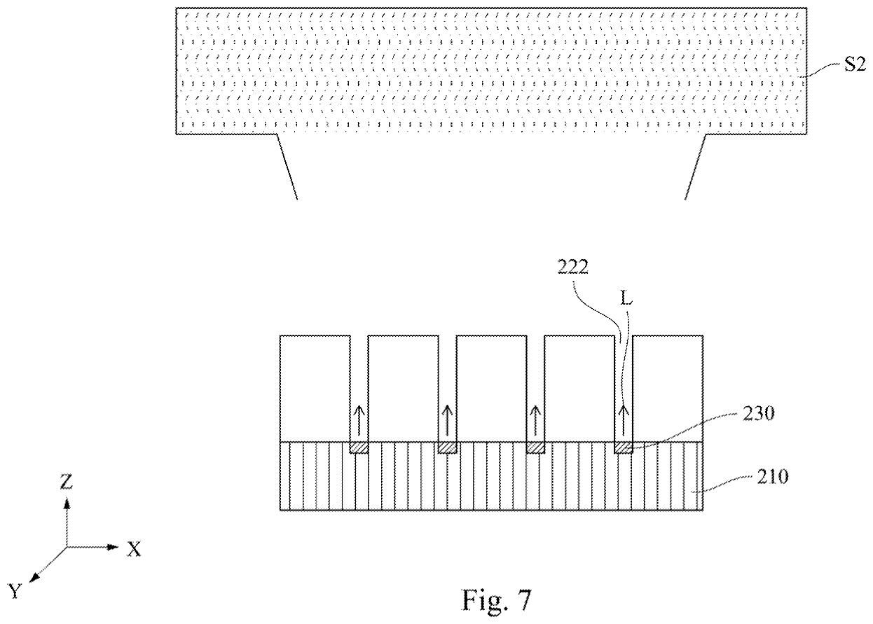

Referring to step S160 of FIG. 1 and FIG. 7, an overlay error of one of the holes 222 is determined according to the luminescent signal L. Specifically, the overlay error of one of the holes 222 is determined by comparing a practical position of one of the holes 222 detected by the luminescent signal L with a theoretical position of one of the holes 222, in which the theoretical position is defined according to alignment marks of the substrate body 210. For example, the overlay error in the x direction can be calculated by the following equation:

practical position in the x direction−theoretical position in the x direction

In some embodiments, the overlay error of each of the holes 222 is determined by comparing the practical position of each one of the holes 222 detected by the luminescent signal L with the theoretical position of each one of the holes 222. In some embodiments, the luminescent signal L is detected to capture a luminescent picture by using a fluorescence microscope S2. In some embodiments, the luminescent picture obtained by the fluorescence microscope S2 and the surface image obtained by the charged particle source S1 (referring to FIG. 6) can be combined to define the practical position of the hole 222 more precisely. It should be noted that the practical position of the hole 222 can hardly be detected by SEM through secondary electrons E2 (referring to FIG. 6) due to the high aspect ratio of the holes 222. Comparatively, the detection region 230 including the luminescent material LM (not shown in FIG. 7) achieves the detection of the practical position of the hole 222 by using the fluorescence microscope S2 even though the holes 222 has the high aspect ratio.

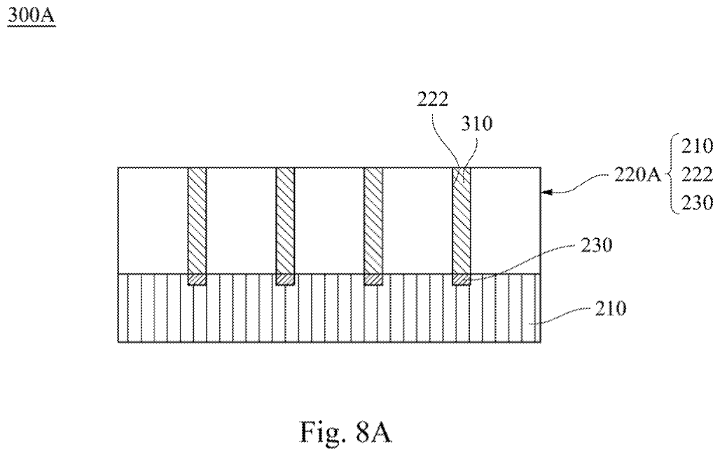

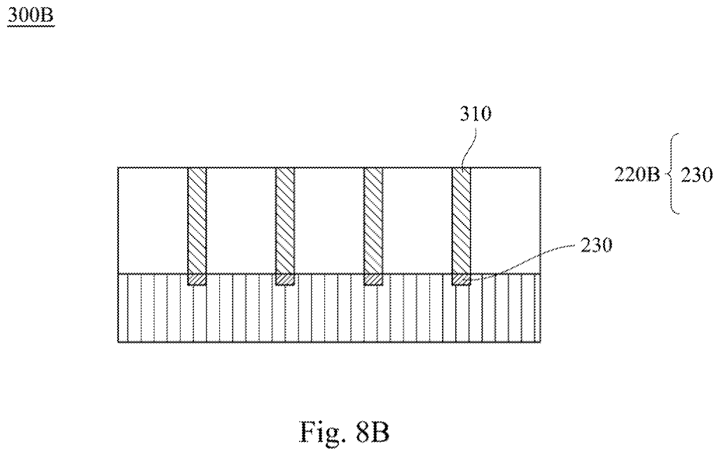

In some embodiments, referring to FIG. 8A, the filling pillars 310 are disposed on the detection regions 230 of the semiconductor device 200A to form a semiconductor device 300A once the overlay error of the hole 222 is within an acceptable range. That is, the overlay error of the hole 222 is determined before the formation of the filling pillars 310 in case of unacceptable bias of the filling pillars 310 caused by the bias of the holes 222. In some embodiments, each one of the filling pillars 310 is disposed on each one of the detection regions 230. For example, each one of the filling pillars 310 is directly disposed on each one of the detection regions 230 and fills up each one of the holes 222.

In some embodiments, the filling pillar 310 includes a third metal material, is directly disposed on the detection regions 230 and fills up the holes 222. For example, the filling pillar 310 can be served as a contact for contacting with a capacitor (not shown in FIG. 8A). It should be emphasized that while the substrate body 210 and the filling pillar 310 are conductive, the interference of the detection regions 230 to the current flowing through the substrate body 210 and the filling pillar 310 can be reduced by selecting the conductive material (such as second metal material) to be the material of the detection regions 230.

In some embodiments, referring to FIG. 8B, FIG. 8B is basically similar to FIG. 8A. The difference of FIG. 8B and FIG. 8A is that the semiconductor device 300B of FIG. 8B displays the filling pillars 310 are disposed on the detection regions 230 of the semiconductor device 200B.

Some embodiments of the present disclosure provide a semiconductor device and method of manufacturing the semiconductor device. The semiconductor device includes the detection regions correspond to the holes of the overlapping layer, and the detection region includes the luminescent material. With the luminescent material of the detection regions, the overlay error of the holes with the high aspect ratio can successfully be determined.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A semiconductor device comprising:
a substrate, wherein the substrate has a substrate body and a plurality of detection regions disposed on a top surface of the substrate body, wherein one of the plurality of detection regions includes a luminescent material; and
an overlapping layer disposed on the substrate body, wherein the overlapping layer has a plurality of holes, and each one of the plurality of detection regions corresponds to each one of the plurality of holes.

2. The semiconductor device of claim 1, wherein the top surface of the substrate body has a plurality of recesses, and each one of the plurality of detection regions corresponds to and is disposed in each one of the plurality of recesses.

3. The semiconductor device of claim 1, wherein a top surface of the plurality of detection regions is coplanar with the top surface of the substrate body, and the substrate body surrounds a bottom portion of each one of the plurality of detection regions.

4. The semiconductor device of claim 3, wherein the substrate body includes a first metal material, and one of the plurality of detection regions includes a second metal material, wherein the second metal material is the luminescent material.

5. The semiconductor device of claim 4, wherein the luminescent material includes Cu⁺, Ag⁺, In⁺, V²⁺, Co²⁺, Sn²⁺, Eu²⁺, Mn²⁺, Ni²⁺, Pb²⁺, Bi³⁺, Pr³⁺, Nd³⁺, Sm³⁺, Eu³⁺, Gd³⁺, Tb³⁺, Dy³⁺, Ho³⁺, Tm³⁺, Yb³⁺, Ti³⁺, Ce³⁺, or a combination thereof.

6. The semiconductor device of claim 1, wherein each one of the plurality of detection regions corresponds to and is disposed in each one of the plurality of holes, and a bottom surface of each one of the plurality of detection regions is coplanar with the top surface of the substrate body.

7. The semiconductor device of claim 1, wherein one of the plurality of holes has an aspect ratio of from 5:1 to 100:1.

8. The semiconductor device of claim 1, further comprising a plurality of filling pillars, wherein each one of the plurality of filling pillars is disposed on each one of the plurality of detection regions.

9. The semiconductor device of claim 8, wherein each one of the plurality of filling pillars is directly disposed on each one of the plurality of detection regions and fills up each one of the plurality of holes.

10. A method of manufacturing a semiconductor device comprising:
providing a substrate body;
disposing an overlapping layer on the substrate body;
forming a plurality of holes in the overlapping layer and exposing an exposed portion of the substrate body;
disposing a plurality of detection regions on the substrate body or in the substrate body through the plurality of holes, wherein one of the plurality of detection regions includes a luminescent material;
providing an electron beam propagating toward the plurality of detection regions to emit a luminescent signal from one of the plurality of detection regions; and
determining an overlay error of the plurality of holes by comparing a practical position of one of the plurality of holes detected by the luminescent signal with a theoretical position of one of the plurality of holes.

11. The method of claim 10, wherein disposing the plurality of detection regions on the substrate body through the plurality of holes comprises disposing a detection material comprising the luminescent material on the exposed portion of the substrate body.

12. The method of claim 10, wherein disposing the plurality of detection regions in the substrate body through the plurality of holes comprises doping the luminescent material in the substrate body by an ion-implanting method.

13. The method of claim 12, wherein the substrate body includes a first metal material, and the luminescent material is a second metal material.

14. The method of claim 10, further comprising:
providing the electron beam propagating toward the overlapping layer while providing an electron beam propagating toward the plurality of detection regions; and
determining a surface image of the overlapping layer by detecting secondary electrons reflected by the overlapping layer.

15. The method of claim 10, further comprising disposing a plurality of filling pillars on the plurality of detection regions.
